(19) United States
(12) Patent Application Publication
(10) Pub. No.: US 2024/0266454 A1
(43) Pub. Date: Aug. 8, 2024

(54) Flexible and Rollable Self-Floating and Self-Buoyant Solar Panels and Photovoltaic Devices

(71) Applicant: SOLARPAINT LTD., YOKNEAM ILLIT (IL)

(72) Inventors: Eran Maimon, Kibbutz Nahsholim (IL); Ramon Joseph Albalak, Haifa (IL)

(21) Appl. No.: 18/372,720

(22) Filed: Sep. 26, 2023

Related U.S. Application Data
(63) Continuation of application No. PCT/IL2022/050339, filed on Mar. 29, 2022.
Application No. PCT/IL2022/050339 is a continuation-in-part of application No. PCT/IL2021/051202, filed on Oct. 8, 2021.
Application No. PCT/IL2021/051202 is a continuation-in-part of application No. PCT/IL2021/051269, filed on Oct. 27, 2021.
Application No. PCT/IL2021/051269 is a continuation-in-part of application No. PCT/IL2022/050030, filed on Jan. 10, 2022.
Application No. PCT/IL2022/050030 is a continuation-in-part of application No. 17/353,867, filed on Jun. 22, 2021, now Pat. No. 11,978,815.
(63) Continuation-in-part of application No. 17/353,867, filed on Jun. 22, 2021, now Pat. No. 11,978,815.
Application No. 17/353,867 is a continuation-in-part of application No. 16/362,665, filed on Mar. 24, 2019, now Pat. No. 11,081,606.
Application No. 17/353,867 is a continuation-in-part of application No. PCT/IL2019/051416, filed on Mar. 24, 2019.
Application No. PCT/IL2019/051416 is a continuation-in-part of application No. 16/362,665, filed on Mar. 24, 2019, now Pat. No. 11,081,606.
Application No. PCT/IL2022/050030 is a continuation-in-part of application No. 17/802,335, filed on Aug. 25, 2022.
(63) Continuation-in-part of application No. 18/129,865, filed on Apr. 2, 2023.
Application No. 18/129,865 is a continuation-in-part of application No. PCT/IL2021/051202, filed on Oct. 7, 2021.
Application No. PCT/IL2021/051202 is a continuation-in-part of application No. 17/353,867, filed on Jun. 22, 2021, now Pat. No. 11,978,815.
(63) Continuation-in-part of application No. 18/136,359, filed on Apr. 19, 2023.
Application No. 18/136,359 is a continuation-in-part of application No. PCT/IL2021/051269, filed on Oct. 27, 2021.
Application No. PCT/IL2021/051269 is a continuation-in-part of application No. 17/353,867, filed on Jun. 22, 2021, now Pat. No. 11,978,815.
(63) Continuation-in-part of application No. 17/802,335, filed on Aug. 25, 2022.
(63) Continuation-in-part of application No. 18/217,620, filed on Jul. 3, 2023.
Application No. 18/217,620 is a continuation of application No. PCT/IL2022/050030, filed on Jan. 10, 2022.
(60) Provisional application No. 63/167,660, filed on Mar. 30, 2021.
(60) Provisional application No. 62/785,282, filed on Dec. 27, 2018.
(60) Provisional application No. 62/785,282, filed on Dec. 27, 2018.
(60) Provisional application No. 62/982,536, filed on Feb. 27, 2020.
(60) Provisional application No. 63/088,535, filed on Oct. 7, 2020.
(60) Provisional application No. 63/106,666, filed on Oct. 28, 2020.

(51) Int. Cl. H01L 31/0445; H01L 31/0224; H01L 31/18

(52) U.S. Cl. CPC H01L 31/0445; H01L 31/022458; H01L 31/186

(57) ABSTRACT

A self-floating, rollable, flexible, photovoltaic article includes: (a) a plurality of flexible and rollable and mechanically-resilient solar cells that are inter-connected as a generally planar array that is also flexible and rollable; and (b) a self-buoyant low-density rollable and flexible floating-capability providing layer, that is integrally attached and is non-removably connected, via a non-detachable connection mechanism, to a bottom side or a top side or the generally planar array of flexible and rollable solar cells, or integrally encapsulates the flexible and rollable solar cells, or is integrally sandwiched within the flexible and rollable solar cells. The overall Specific Weight of an entirety of the photovoltaic article is smaller than 1.00.

### CROSS-REFERENCE TO RELATED APPLICATIONS

This patent application is a Continuation of PCT international application number PCT/IL2022/050339, having an international filing date of Mar. 29, 2022, which is hereby incorporated by reference in its entirety.

The above-mentioned PCT/IL2022/050339 claims priority and benefit from U.S. 63/167,660, filed on Mar. 30, 2021, which is hereby incorporated by reference in its entirety.

The above-mentioned PCT/IL2022/050339 also claims priority and benefit from PCT international application number PCT/IL2021/051202, having an international filing date of Oct. 8, 2021, which is hereby incorporated by reference in its entirety.

The above-mentioned PCT/IL2022/050339 also claims priority and benefit from PCT international application number PCT/IL2021/051269, having an international filing date of Oct. 27, 2021, which is hereby incorporated by reference in its entirety.

The above-mentioned PCT/IL2022/050339 also claims priority and benefit from PCT international application number PCT/IL2022/050030, having an international filing date of Jan. 10, 2022, which is hereby incorporated by reference in its entirety.

The above-mentioned PCT/IL2022/050339 also claims priority and benefit from patent application U.S. Ser. No. 17/353,867, filed on Jun. 22, 2021, which is hereby incorporated by reference in its entirety.

This patent application is also a Continuation-in-Part (CIP) of U.S. Ser. No. 17/353,867, filed on Jun. 22, 2021, which is hereby incorporated by reference in its entirety.

The above-mentioned U.S. Ser. No. 17/353,867 is a Continuation-in-Part (CIP) of U.S. Ser. No. 16/362,665, filed on Mar. 24, 2019, now patent number U.S. Pat. No. 11,081,606 (issued on Aug. 3, 2021), which is hereby incorporated by reference in its entirety; which claims priority and benefit from U.S. 62/785,282, filed on Dec. 27, 2018, which is hereby incorporated by reference in its entirety.

The above-mentioned U.S. Ser. No. 17/353,867 is also a Continuation-in-Part (CIP) of PCT international application number PCT/IL2019/051416, having an international filing date of Dec. 26, 2019, which is hereby incorporated by reference in its entirety.

The above-mentioned PCT/IL2019/051416 claims priority and benefit (I) from U.S. Ser. No. 16/362,665, filed on Mar. 24, 2019, now patent number U.S. Pat. No. 11,081,606 (issued on Aug. 3, 2021), which is hereby incorporated by reference in its entirety, and (II) from U.S. 62/785,282, filed on Dec. 27, 2018, which is hereby incorporated by reference in its entirety.

The above-mentioned PCT/IL2022/050030 is also a Continuation-in-Part (CIP) of U.S. Ser. No. 17/802,335, filed on Aug. 25, 2022, which is hereby incorporated by reference in its entirety; which is a National Stage of PCT international application number PCT/IL2021/050217, having an international filing date of Feb. 25, 2021, which is hereby incorporated by reference in its entirety; which claims priority and benefit from U.S. 62/982,536, filed on Feb. 27, 2020, which is hereby incorporated by reference in its entirety.

This patent application is also a Continuation-in-Part (CIP) of U.S. Ser. No. 18/129,865, filed on Apr. 2, 2023, which is hereby incorporated by reference in its entirety. The above-mentioned U.S. Ser. No. 18/129,865 is a Continuation of PCT international patent application number PCT/IL2021/051202, having an international filing date of Oct. 7, 2021, which is hereby incorporated by reference in its entirety. The above-mentioned PCT/IL2021/051202 claims priority and benefit from (i) U.S. 63/088,535, filed on Oct. 7, 2020, which is hereby incorporated by reference in its entirety; and from (ii) U.S. Ser. No. 17/353,867, filed on Jun. 22, 2021, which is hereby incorporated by reference in its entirety.

This patent application is also a Continuation-in-Part (CIP) of U.S. Ser. No. 18/136,359, filed on Apr. 19, 2023, which is hereby incorporated by reference in its entirety. The above-mentioned U.S. Ser. No. 18/136,359 is a Continuation of PCT international application number PCT/IL2021/051269, having an international filing date of Oct. 27, 2021, which is hereby incorporated by reference in its entirety. The above-mentioned PCT/IL2021/051269 claims priority and benefit: (i) from U.S. 63/106,666, filed on Oct. 28, 2020, which is hereby incorporated by reference in its entirety; and also, (ii) from U.S. Ser. No. 17/353,867, filed on Jun. 22, 2021, which is hereby incorporated by reference in its entirety.

This patent application is also a Continuation-in-Part (CIP) of U.S. Ser. No. 17/802,335, filed on Aug. 25, 2022, which is hereby incorporated by reference in its entirety; which is a National Stage of PCT international application number PCT/IL2021/050217, having an international filing date of Feb. 25, 2021, which is hereby incorporated by reference in its entirety; which claims priority and benefit from U.S. 62/982,536, filed on Feb. 27, 2020, which is hereby incorporated by reference in its entirety.

This patent application is also a Continuation-in-Part (CIP) of U.S. Ser. No. 18/217,620, filed on Jul. 3, 2023, which is hereby incorporated by reference in its entirety; which is a Continuation of the above-mentioned PCT international application number PCT/IL2022/050030, having an international filing date of Jan. 10, 2022, which is hereby incorporated by reference in its entirety.

### FIELD

Some embodiments relate to the field of solar panels and photovoltaic (PV) devices.

### BACKGROUND

The photovoltaic (PV) effect is the creation of voltage and electric current in a material upon exposure to light. It is a physical and chemical phenomenon.

The PV effect has been used in order to generate electricity from sunlight. For example, PV solar panels absorb sunlight or light energy or photons, and generate current electricity through the PV effect.

### SUMMARY

Some embodiments provide flexible and rollable self-floating and/or self-buoyant and/or autonomously-floating solar panels and photovoltaic devices, which may be provided in roll form or as a roll or a rolled cylinder, or which may be provided in an already-rolled or already-folded form; and which may be un-rolled and/or unfolded, and which may be deployed over or onto a body of water and/or at other locations; and which may float autonomously and/or independently, without requiring to be mounted on a separate floating support device or floatation device.

In some embodiments, a device comprises a self-floating, rollable, flexible, photovoltaic article, that is formed of a plurality of flexible and rollable and mechanically-resilient solar cells that are inter-connected as a generally planar (yet flexible and rollable) array. Each of said flexible and rollable and mechanically-resilient solar cells has (I) a sunny-side or top-side surface that is configured to absorb light, and (II) a back-side or or bottom-side surface that is opposite to said sunny-side surface and is not necessarily configured to absorb light (e.g., in some implementations it does not absorb light and it is a “dark side”; or, in other implementations, it also absorbs light and it is a “sunny side”). Each of said flexible and rollable and mechanically-resilient solar cells is configured to generate electric current from light via the photovoltaic effect. The generally-planar array of flexible and rollable and mechanically-resilient solar cells, is bonded or glued or attached to, or is non-detachably attached to, or is encapsulated within, a polymeric and/or foamed layer or encapsulation layer or coating or encapsulation layers or support layers or foamed layers or low-density layer(s) or low-Specific-Weight layer(s), which may be beneath the solar cells and/or within the solar cells and/or covering on top of the solar cells (e.g., being transparent or translucent) and/or bonded to one or more sides or borders of the solar cells, such that the overall Specific Weight of the device is smaller than 1.00 and thus the device is self-buoyant or self-floating over water.

In some embodiments, additionally or alternatively, a low-density (or reduced-density, or foamed polymers) rollable and flexible layer, such as foamed polymer(s), is bonded and/or glued and/or non-detachably attached and/or non-removably attached and/or integrally attached beneath the bottom side or beneath the lowest surface of the photovoltaic article, and provides a self-buoyancy property to the entirety of the photovoltaic article; such that the overall Specific Weight of the device is smaller than 1.00 and thus the device is self-buoyant or self-floating over water.

In some embodiments, additionally or alternatively, a low-density (or reduced-density, or foamed polymers) rollable and flexible layer, such as foamed polymer(s), is bonded and/or glued and/or non-detachably attached and/or integrally attached and/or non-removably attached at a side (e.g., right side and/or left side) of the photovoltaic article, and provides a self-buoyancy property to the entirety of the photovoltaic article; such that the overall Specific Weight of the device is smaller than 1.00 and thus the device is self-buoyant or self-floating over water.

In some embodiments, additionally or alternatively, a low-density rollable and flexible layer, such as foamed polymer(s), is bonded and/or glued and/or non-detachably attached and/or integrally attached and/or non-removably internally attached (or sandwiched, or encapsulated) within two of the already-existing layers of the solar cells (e.g., at one or more suitable locations between the top-most surface of the solar cells and the lowest surface of the solar cells), and/or is entirely or at least partially encapsulated or sandwiched within other layers of the solar cells, and provides a self-buoyancy property to the entirety of the photovoltaic article; such that the overall Specific Weight of the device is smaller than 1.00 and thus the device is self-buoyant or self-floating over water.

In some embodiments, additionally or alternatively, a low-density (or reduced-density, or foamed polymers) rollable and flexible layer, such as foamed polymer(s), is bonded and/or glued and/or non-detachably attached and/or integrally attached and/or non-removably attached on top of the top-most surface or upper-most surface of the solar cells, and may be transparent or translucent (e.g., allowing full or at least partial of light there-through), and provides a self-buoyancy property to the entirety of the photovoltaic article; such that the overall Specific Weight of the device is smaller than 1.00 and thus the device is self-buoyant or self-floating over water.

Some embodiments provide a self-floating, rollable, flexible, photovoltaic article that includes: (a) a plurality of flexible and rollable and mechanically-resilient solar cells that are inter-connected as a generally planar array that is also flexible and rollable; and (b) a self-buoyant low-density rollable and flexible floating-capability providing layer, that is integrally attached and is non-removably connected, via a non-detachable connection mechanism, to a bottom side or a top side or the generally planar array of flexible and rollable solar cells, or integrally encapsulates the flexible and rollable solar cells, or is integrally sandwiched within the flexible and rollable solar cells. The overall Specific Weight of an entirety of the photovoltaic article is smaller than 1.00.

Some embodiments may provide other and/or additional benefits and/or advantages.

### BRIEF DESCRIPTION OF THE DRAWINGS

FIG. 1A is a schematic illustration of a rolled, self-floating, flexible photovoltaic article, in accordance with some demonstrative embodiments.

FIG. 1B is a schematic illustration of a cross-sectional view (along the A-A cross section) of a rolled, self-floating, flexible photovoltaic article, in accordance with some demonstrative embodiments.

FIG. 1C is an enlarged or zoomed-in view of a portion of that cross-sectional view (along the A-A cross section) of a rolled, self-floating, flexible photovoltaic article, in accordance with some demonstrative embodiments.

FIGS. 2A and 2B are perspective-view illustrations of rollable and flexible, mechanically resilient, shock absorbing, solar cells or photovoltaic modules, in accordance with some demonstrative embodiments.

FIGS. 3A-3D are perspective-view illustration of rollable and flexible, mechanically resilient, shock absorbing, photovoltaic articles, in accordance with some demonstrative embodiments.

### DETAILED DESCRIPTION OF SOME DEMONSTRATIVE EMBODIMENTS

The Applicants have realized that conventional solar panels are typically rigid, heavy, cumbersome, brittle and/or fragile units, that are typically installed on roofs or in other locations (e.g., a solar energy park, a solar energy farm, a solar power plant). A conventional solar panel often has a large form-factor (e.g., 1 by 2 meters), and is heavy (e.g., 25 kilograms).

The Applicants have realized that a conventional solar panel cannot float, by itself, on water or fresh water or salt water or sea water. A conventional solar panel, realized the Applicants, is often made of silicon and has a heavy glass top-layer and an aluminum frame; and would sink and not float in a body of water.

Some conventional solar panels may be placed on top of a separate floating support device, such as, on an already-floating boat or raft. However, realized the Applicants, such conventional, separate, floating support device is typically a large-volume or large-size device (e.g., a boat or a raft), which is cumbersome to transport and/or is expensive to transport and/or is expensive to maintain; which, in turn, high cost per Watt of produced electricity (due to said transport and maintenance costs of the floating support device).

Additionally or alternatively, realized the Applicants, the transport and/or the deployment of a conventional rigid, fragile, brittle, large form-factor solar panel, is often a difficult task; and such conventional panel may break or may become damaged in transport towards the body of water and/or during deployment or mounting onto the floatable support structure; and/or may require complex, expensive, and effort-consuming logistics for such transport and deployment, thus further increasing the cost per Watt of produced electricity.

The Applicants have realized that it may be beneficial and/or advantageous to provide a self-floating or self-buoyant or autonomously-floating solar module, or a self-floating or self-buoyant or autonomously-floating photovoltaic device or photovoltaic module or photovoltaic cell or photovoltaic cell-array. The Applicants have realized that such self-floating or self-buoyant solar panel or photovoltaic device may be deployed on a body of water, for various purposes; for example, to generate electricity on a lake (or water reservoir, or basin) and provide it to a nearby town or factory, to generate electricity in the sea and provide it to a nearby oil rig, to generate electricity on an artificial or man-made pool or lake and provide it to nearby electricity consumers or electric devices, to generate electricity while floating in a body-of-water (e.g., without requiring land occupancy) and providing the generated electric power to an electricity grid, and/or for other purposes.

The Applicants have also realized that such self-floating or self-buoyant solar panel or photovoltaic device may provide other and/or additional benefits; for example, by covering some or all of the surface of the body-of-water, and thus—in addition to generating electricity—also reducing the evaporation of water from the body-of-water, and/or maintaining the quality and/or cleanliness of the water (e.g., by preventing leaves or foliage from falling into the water).

Accordingly, some embodiments provide flexible and rollable self-floating and self-buoyant solar panels and photovoltaic devices, which may be provided in roll form or as a roll or a rolled cylinder, or which may be provided in an already-rolled or already-folded form; and which may be un-rolled and/or unfolded, and which may be deployed over or onto a body-of-water and/or at other locations; and which may float autonomously and/or independently, without requiring to be mounted on a separate floating support device or floatation device; and which may be interconnected to each other with virtually no constraints of size and/or shape and/or electricity production capacity.

Some embodiments provide a unique PV article, comprises of a continuous roll of flexible and rollable energy-producing photovoltaic elements, that are intimately inter-connected to a continuous, flexible, rollable, low-density backing or back-layer or support-layer; thereby forming a self-floating or self-buoyant PV article, which can float on water without the need to be mounted on a separate, bulky, cumbersome and/or expensive floating support structure. Rather, the unique PV article of some embodiments enjoys its own built-in or integrated self-buoyancy property. In some embodiments, the “low density” layer or structure or component, that is integrally bonded or glued or non-removably attached or non-detachably attached to one or more regions or layers of the PV article, has a Specific Weight that is smaller than 1.00, and that is sufficiently low such that the overall Specific Weight of the entirety of the PV article would be smaller than 1.00. In a non-limiting demonstrative example, prior to integrally bonding or attaching such additional “low density” layer(s), the PV article may have an overall Specific Weight of (for example) 1.08, and thus cannot self-float on water; the layer(s) that are integrally bonded or integrally attached or non-removably attached to such PV device may have their own Specific Weight of (for example) 0.82 or 0.85; such that the overall Specific Weight of the entirety of the PV article becomes smaller than 1.00, such as, it may be 0.98 or 0.97, and thus the entirety of the PV article would self-float on water. The “low density” of such added layer(s) or structure(s), that are integrally and non-removably attached to the PV article, or that encapsulate the PV article or that are sandwiched within the PV article, is a “low density” that is configured based on the Specific Weight of the PV article in its pre-attachment status. For example, if the pre-attachment PV article has a Specific Weight of (for example) 1.05, then a first type of foamed layer(s) or low-density layer(s) may be attached (e.g., having a first thickness value and/or volume value, and having its own Specific Weight of, for example, 0.87); whereas, if the pre-attachment PV article has a larger Specific Weight of (for example) 1.08, then a second, different, type of foamed layer(s) or low-density layer(s) may be attached (e.g., having a second, greater thickness value, and/or a second, greater, volume), and having its own, even smaller, Specific Weight of, for example, 0.82).

The self-floating solar panels and PV articles of some embodiments are thus superior to (and are advantageous over, and more efficient than, and are more cost-effective than) conventional attempts to mount a rigid, brittle, fragile, non-floating solar panel, onto a separate, expansive, cumbersome, floating raft of boat or other separate floatation device; and such efficiency may be measured by the volume and/or weight and/or cost of the overall floating and electricity-producing system and/or on a per Watt of electricity produced.

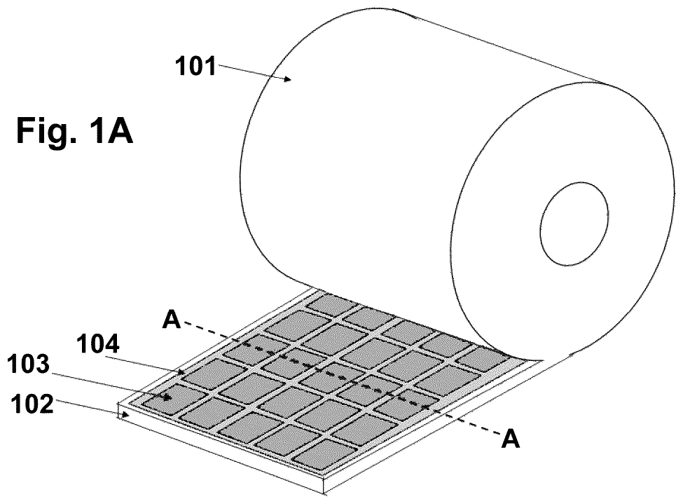

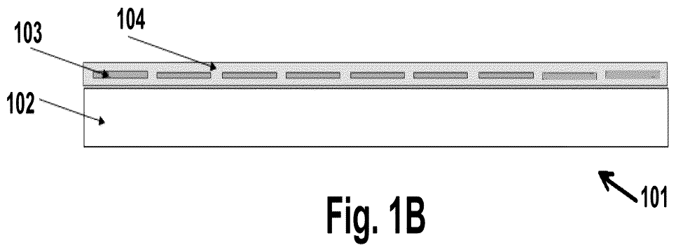

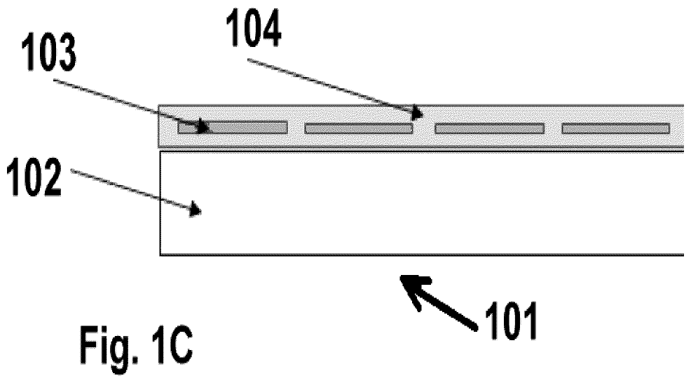

Reference is made to FIG. 1A, which is a schematic illustration of a rolled, self-floating, flexible PV article 101, in accordance with some demonstrative embodiments. Reference is also made to FIG. 1B, which is a schematic illustration of a cross-sectional view (along the A-A cross section) of the rolled, self-floating, flexible PV article 101, in accordance with some demonstrative embodiments. Reference is also made to FIG. 1C, which is an enlarged or zoomed-in view of a portion of that cross-sectional view (along the A-A cross section) of the rolled, self-floating, flexible PV article 101, in accordance with some demonstrative embodiments.

Most of the PV article 101 is shown in rolled form, similar to a cylinder; and a small portion of the PV article 101 is shown in a generally-flat, un-rolled, form. PV article 101 is comprised of a plurality of array or matrix of solar cells 103, each one of them being (by itself) flexible and rollable; and they are inter-connected in an arrangement forming a bulk of solar panels 104; and they are integrally attached or glued, via mechanical and/or thermo-mechanical glue-based connection, to a rollable and flexible floating medium 102, which provides to them (and to their integrated combination) the required buoyancy property. Electrodes or electrical connections or wires are used (but are not shown, to avoid over-crowding of the drawing), in order to provide the electric current or the electric voltage that are generated and outputted by the PV article 101.

Each one of the flexible and rollable solar cells 103, may be a flexible and rollable and mechanically-resilient PV cell or solar panel is formed of a single semiconductor wafer. The PV cell has a sunny-side surface (or an active-side surface) that is configured to absorb light. The PV cell has a dark-side surface (or an inactive-side surface) that is opposite to said sunny-side surface and that is not configured to absorb light. The PV cell is configured to generate electric current and/or electric voltage from light or from light energy or from photons, via the PV effect. The PV cell comprises a plurality of non-transcending craters, that penetrate upwardly from the dark-side surface towards the sunny-side surface but do not reach said sunny-side surface; wherein those non-transcending craters penetrate upwardly into between 80 to 99.9 percent of the height of the semiconductor wafer, and they segment the semiconductor wafer into a plurality of miniature sub-regions. Each sub-region has a surface area or a footprint area, measured at the sunny-side surface of the PV cell, in a range of 0.1 to 500 square-millimeters. The plurality of non-transcending craters and the plurality of miniature sub-regions cause the PV cell to have improved properties of mechanical resilience and mechanical shock absorption and shock dissipation, and to be flexible and rollable and non-brittle and non-fragile.

In some embodiments, the PV cell further comprises: (a) a top-side set of conducting wires, that are mechanically connected immediately on top of the sunny-side surface; wherein the top-side set of conducting wires collect and transport only a first polarity type of electric charge, that is either negative electric charge or positive electric charge, that is generated by the PV effect; and also, (b) a bottom-side set of conducting wires, that are mechanically connected immediately beneath the dark-side surface; wherein the bottom-side set of conducting wires collect and transport only a second and opposite polarity type of electric charge, that is either positive electric charge or negative electric charge, that is generated by the PV effect.

In some embodiments, the top-side set of conducting wires comprises a set of generally-parallel conducting wires, spaced apart from each other (e.g., as non-limiting examples, at a distance of between 1 to 5 or 10 or 20 or 30 or 40 or 50 millimeters from each other, or at other suitable distances), which collect and transport only the first polarity type of electric charge that is generated by the PV effect; wherein the bottom-side set of conducting wires comprises a set of generally-parallel conducting wires, spaced apart from each other (e.g., as non-limiting examples, at a distance of between 1 to 5 or 10 or 20 or 30 or 40 or 50 millimeters from each other, or at other suitable distances), which collect and transport only the second polarity type of electric charge that is generated by the PV effect; wherein each sub-region, of at least 50 percent of the plurality of sub-regions of the PV cell, touches at a top side of said sub-region at least one conducting wire of the top-side set of conducting wires, and also touches at a bottom side of said sub-region at least one conducting wire of the bottom-side set of conducting wires.

In some embodiments, the top-side set of conducting wires comprises a set of zigzag-structured conducting wires, spaced apart from each other (e.g., as non-limiting examples, at a distance of between 1 to 5 or 10 or 20 or 30 or 40 or 50 millimeters from each other, or at other suitable distances), which collect and transport only the first polarity type of electric charge that is generated by the PV effect; wherein the bottom-side set of conducting wires comprises a set of generally-parallel conducting wires, spaced apart from each other (e.g., as non-limiting examples, at a distance of between 1 to 5 or 10 or 20 or 30 or 40 or 50 millimeters from each other, or at other suitable distances), which collect and transport only the second polarity type of electric charge that is generated by the PV effect; wherein each sub-region, of at least 50 percent of the plurality of sub-regions of the PV cell, touches at a top side of said sub-region at least one conducting wire of the top-side set of conducting wires, and also touches at a bottom side of said sub-region at least one conducting wire of the bottom-side set of conducting wires.

In some embodiments, the top-side set of conducting wires comprises a set of curved or non-linear conducting wires, spaced apart from each other (e.g., as non-limiting examples, at a distance of between 1 to 5 or 10 or 20 or 30 or 40 or 50 millimeters from each other, or at other suitable distances), which collect and transport only the first polarity type of electric charge that is generated by the PV effect; wherein the bottom-side set of conducting wires comprises a set of generally-parallel conducting wires, spaced apart from each other (e.g., as non-limiting examples, at a distance of between 1 to 5 or 10 or 20 or 30 or 40 or 50 millimeters from each other, or at other suitable distances), which collect and transport only the second polarity type of electric charge that is generated by the PV effect; wherein each sub-region, of at least 50 percent of the plurality of sub-regions of the PV cell, touches at a top side of said sub-region at least one conducting wire of the top-side set of conducting wires, and also touches at a bottom side of said sub-region at least one conducting wire of the bottom-side set of conducting wires.

In some embodiments, the top-side set of conducting wires comprises intersecting conducting wires, which collect and transport only the first polarity type of electric charge that is generated by the PV effect; wherein the bottom-side set of conducting wires comprises a set of generally-parallel conducting wires, spaced apart from each other (e.g., as non-limiting examples, at a distance of between 1 to 5 or 10 or 20 or 30 or 40 or 50 millimeters from each other, or at other suitable distances), which collect and transport only the second polarity type of electric charge that is generated by the PV effect; wherein each sub-region, of at least 50 percent of the plurality of sub-regions of the PV cell, touches at a top side of said sub-region at least one conducting wire of the top-side set of conducting wires, and also touches at a bottom side of said sub-region at least one conducting wire of the bottom-side set of conducting wires.

In some embodiments, the top-side set of conducting wires comprises a set of conducting wires that are embedded within a top-side transparent flexible adhesive foil of plastic material, which mechanically adheres the top-side set of conducting wires to the sunny-side surface, and which enables passage of light through the top-side transparent adhesive foil of plastic material towards the sunny-side surface; wherein the bottom-side set of conducting wires comprises a set of conducting wires that are embedded within a bottom-side flexible adhesive foil of plastic material, which mechanically adheres the bottom-side set of conducting wires to the dark-side surface.

In some embodiments, the top-side set of conducting wires comprises a set of top-side non-soldered, molten or partially molten and resolidified, conducting wires that are formed of an alloy of metals, wherein said alloy has a melting temperature that is lower than 150 degrees Celsius; wherein each conducting wire of the top-side set of conducting wires is connected to the sunny-side surface via a solder-less connection formed of solidified molten alloy.

In some embodiments, the bottom-side set of conducting wires comprises a bottom-side set of non-soldered, molten or partially molten and resolidified, conducting wires that are formed of an alloy of metals, wherein said alloy has a melting temperature that is lower than 150 degrees Celsius; wherein each conducting wire of the bottom-side set of conducting wires is connected to the dark-side surface via a solder-less connection formed of solidified molten alloy.

In some embodiments, the sunny-side surface is covered by the top-side set of conducting wires that are spaced-apart (e.g., as non-limiting examples, at a distance of 1 or 2 or 5 or 8 or 10 millimeters, or at a distance that is between 1 and 5 or 10 or 20 or 30 or 40 or 50 millimeters, or at other suitable distances); wherein said distance is sufficiently small to enable efficient collection of the first polarity type of electric charge from the sunny-side surface of the PV cell; wherein said distance is sufficiently large to minimize obstruction of incoming light by said top-side set of conducting wires as incoming light travels towards the sunny-side surface that is located beneath said top-side set of conducting wires.

In some embodiments, the dark-side surface is covered, from beneath, by the bottom-side set of conducting wires that are spaced-apart (e.g., as non-limiting examples, at a distance of 1 or 2 or 5 or 8 or 10 millimeters, or at a distance that is between 1 and 5 or 10 or 20 or 30 or 40 or 50 millimeters, or at other suitable distances); wherein said distance is sufficiently small to enable efficient collection of the second polarity type of electric charge from the dark-side surface of the PV cell.

In some embodiments, the bottom-side set of conducting wires comprises a set of conducting wires that are embedded within a bottom-side flexible adhesive foil of plastic material, which mechanically adheres the bottom-side set of conducting wires to the dark-side surface; wherein at least a portion of the bottom-side flexible adhesive foil of plastic material fills, at least partially, said non-transcending craters and provides to said PV cell improved properties of mechanical resilience and mechanical shock absorption and shock dissipation.

In some embodiments, the bottom-side flexible adhesive foil of plastic material is a component selected from the group consisting of: a high-elasticity stretchable polyolefin film, a rigid-flex polyester (PET) film, a rigid polyester (PET) film. In some embodiments, the top-side transparent flexible adhesive foil of plastic material is a component selected from the group consisting of: a high-elasticity stretchable polyolefin film, a rigid-flex polyester (PET) film, a rigid polyester (PET) film.

In some embodiments, the top-side set of conducting wires, that is attached over an upper side of the sunny-side surface of the PV cell, is non-planar and is non-flat to improve an overall elasticity of said flexible and mechanically-resilient PV cell. In some embodiments, the bottom-side set of conducting wires, that is attached beneath a lower side of the dark-side surface of the PV cell, is non-planar and is non-flat to improve an overall elasticity of said flexible and mechanically-resilient PV cell.

In some embodiments, optionally, the sub-regions are structured as a flexible, mechanically-resilient, elongated, string of segmented sub-regions that convert light into electricity via the PV effect; wherein each string of segmented sub-regions has its own laminated all-around coating that separates said string from other, nearby, strings. In other embodiments, each all the sub-regions are encapsulated together, and not discretely or separately, within a single lamination layer.

In some embodiments, the alloy of metals, that mechanically and electrically connects said top-side set of conducting wires above the sunny-side surface of the PV cell, comprises one or more of: a solidified molten alloy of indium and another metal; a solidified molten alloy of indium and tin; a solidified molten alloy of bismuth and another metal; a solidified molten alloy of bismuth and tin; a solidified molten alloy having a melting temperature that is lower than 150 degrees Celsius. Additionally or alternatively, in some embodiments, the alloy of metals, that mechanically and electrically connects said bottom-side set of conducting wires beneath the dark-side surface of the PV cell, comprises one or more of: a solidified molten alloy of indium and another metal; a solidified molten alloy of indium and tin; a solidified molten alloy of bismuth and another metal; a solidified molten alloy of bismuth and tin; a solidified molten alloy having a melting temperature that is lower than 150 degrees Celsius.

In some embodiments, each one of the flexible and rollable solar cells 103, is a segmented photovoltaic (PV) cell or cell-array, having a plurality of sub-regions or micro sub-regions. The PV cell or cell-array includes a single wafer or a single substrate or a single semiconductor substrate, that is segmented via a plurality of craters or non-transcending gaps or “blind gaps”. Each crater penetrates downwardly (or upwardly, from the bottom side of the solar cell; from the “dark side” to the “sunny side” of the solar cell), into some of the depth, or most of the depth, or at least 75 percent of the depth, or between 75 to 99 percent of the depth, but not through an entire 100 percent of the depth, of the single wafer or the single substrate or the single semiconductor substrate. Each crater or non-transcending gap or “bling gap” begins at a first surface of the single wafer or the single substrate or the single semiconductor substrate. Each crater creates a physical gap or segmentation between two neighboring sub-regions, but without entirely separating their common wafer layer or substrate layer from each other. In the final product, the sub-regions are still connected to each other, mechanically and electrically, via a thin layer of the single wafer or the single substrate or the single semiconductor substrate that is not divided and is not fully penetrated via any crater or any “bling gap”. In some embodiments, each sub-region has a top surface area that is smaller than one square centimeter; or that is in the range of 0.1 to 1 square millimeter. The segmentation of that single wafer or the single substrate or the single semiconductor substrate via such numerous craters, and the inclusion of such craters among the sub-regions, inhibits or reduces mechanical breakage of the solar cell or the PV cell or the PV device, and/or provides resilience or mechanical resilience to the solar cell or the PV cell or the PV device, and/or assists in absorbing and/or dissipating mechanical shocks and/or mechanical forces, and/or prevents or reduces breakage of the solar cell or the PV device or the PV cell, and/or enables the solar cell or the PV device or PV cell to be rollable and/or foldable and/or bendable and/or flexible and/or semi-flexible.

In accordance with some embodiments, the rollable and flexible floating medium 102 is a rollable and flexible low-density material; wherein the overall density of the PV article 101 is sufficiently low to enable the entirety of the PV article 101 to autonomously float on water or fresh water or salty water or sea water or on a body of water, without the need to mount such integrated and self-buoyant PV article to a floating support structure or a floating support device.

In some embodiments, the solar cells comprising the flexible and rollable PV article 101 are based on (or are formed of, or comprise) one or more of: monocrystalline silicon, polycrystalline silicon, interdigitated back connectors (IBC) cells, bi-facial cells, or a combination of two or more of the above and/or other suitable flexible PV device technologies, sch as Organic PV (OPB) modules that are prepared using ambient roll-to-roll printing and coating, perovskite solar cell (PSC) (e.g., using a hybrid organic-inorganic lead or tin halide-based material as the light-harvesting active layer), Copper Indium Gallium Diselenide (CIGS) based solar cells or thin-film PV modules, Gallium Arsenide (GaAs) based solar cells, Cadmium Telluride (CdTe) based solar cells, or the like.

In some embodiments, the flexible and rollable low-density floating medium, to which the flexible and rollable array of solar cells is attached, is (or comprises) a foam of low-density polyethylene and/or medium-density polyethylene and/or high-density polyethylene and/or polypropylene and/or polyurethane and/or other suitable polymers or foam-able polymers.

In some embodiments, the flexible and rollable low-density floating medium, to which the flexible and rollable array of solar cells is attached, is (or comprises) a foam having closed-cell pores. Such pores may be, for example, pores that were manufactured in the production of the foam layer or foam film, and/or pores that are inflated during the manufacturing process, and/or pores that are inflated on site (e.g., upon touching water, or upon exposure to sunlight or Ultra Violet (UV light), or upon exposure to heat at a pre-defined minimum temperature, or upon exposure to electric current or electric voltage).

In some embodiments, the flexible and rollable array of solar cells is attached to the flexible and rollable low-density floating medium, via a process in which a flame is used to heat and melt a top surface of the flexible and rollable low-density floating medium, wherein the top surface thereof is brought into contact with the bottom side of the flexible and rollable array of solar cells; and the molten or melted top surface of the low-density floating medium attaches to the bottom side of the flexible and rollable array of solar cells; and they become an integrated, singular, article upon the solidifying of such molten or melted top surface of the low-density floating medium.

In some embodiments, the roll of photovoltaic modules contains a single PV module, having an overall electrical capacity production of up to 350 Watts, and having an un-rolled area of between 1 to 2 square meters.

In some embodiments, the roll of photovoltaic modules contains up to five PV modules; having an overall electrical capacity production of up to 350 Watts, and having an un-rolled area of between 1 to 2 square meters.

In some embodiments, the roll of photovoltaic modules contains six to ten PV modules; having an overall electrical capacity production of 350 to 3,500 Watts, and having an un-rolled area of between up to 10 square meters.

In some embodiments, the roll of photovoltaic modules contains over ten PV modules; having an overall electrical capacity production of over 1,000 Watts, and having an un-rolled area of over 10 square meters.

In some embodiments, the flexible and rollable PV article includes one or more junction boxes, through which the PV article is electrically connected. In other embodiments, an alternative method to a junction box is used for the purpose of electrical connectivity, for example, by utilizing insulated conductors that run between the internal terminals of the matrix or array of flexible solar cells in the PV article, wherein external terminals of the PV article are incorporated in the PV article during its manufacturing.

In some embodiments, the flexible and rollable PV article includes one or more additional layer(s) or support layer(s) or tension bearing layer(s) or tension supporting layer(s); such as a woven or non-woven fabric or net or layer which may be formed of polypropylene (PP), thermoplastic polymer(s), polyamide, polyimide, aramid, polyethylene terephthalate (PET), and/or other material(s). In some embodiments, such additional support layer is also rollable and flexible. In some embodiments, the additional support layer is glued or attached beneath the floating medium. In some embodiments, the additional support layer is glued or attached between the floating medium and the array of solar cells. In some embodiments, a first additional support layer is glued or attached between the floating medium and the array of solar cells, and a second additional support layer is glue or attached beneath the floating medium.

In some embodiments, the rollable and flexible PV article is deployed and used as a self-floating electricity generating surface, that floats over a natural body of water (e.g., natural lake, river, sea, basin) or over a man-made or artificial body of water (e.g., artificial lake, or a water reservoir behind a damn), or over a receptacle of water (e.g., a swimming pool).

In some embodiments, the rollable and flexible PV article is implemented as a self-floating swimming pool cover; and generates electricity from light, while covering the swimming pool, preventing the water in the pool from being contaminated and/or from leaves or objects, and/or preventing people and animals from falling into the pool or from entering the pool.

In some embodiments, the rollable and flexible PV article is implemented as a self-floating electricity-generating floating surface on marine life rafts, or as an electricity-generating floating surface that accompanies marine life rafts.

In some embodiments, the rollable and flexible PV article is implemented as a self-floating electricity-generating floating surface of (or on) an escape shoot or inflatable escape shoot of an aircraft.

In some embodiments, the rollable and flexible PV article is implemented as a self-floating electricity-generating floating surface that accompanies (or provides electricity to) a rig or oil rig or gas rig or oil platform or gas platform, or an oil/gas production platform, or an oil/gas drilling platform, and/or other structure that extracts petroleum or natural gas or other resources from the sea or from a body of water.

In some embodiments, the rollable and flexible PV article includes (or can be connected or attached to) an additional protective/backing material or layer, to enable or to facilitate placement of the PV article on a rough terrain as an alternative deployment of the PV article as self-floating over water.

In some embodiments, the rollable and flexible PV article includes a top-sheet or a top layer having a pre-defined design or logo or camouflage, or having a particular color (e.g., different from a transparent (glossy or matte) surface finish). The top-sheet may be of a uniform color; or of two or more colors; or may have a camouflage structure or paint pattern that resembles a particular type of terrain (e.g., desert, forest, field), optionally being suitable for military use, or for being deployed in civil places or open spaces without being noticeably different from its surrounding natural environment.

Additionally or alternatively, in some embodiments, the top surface or at least a portion of the top surface of the device, and/or a side surface or a portion thereof, may be coated with translucent paint or coating or layer, which reduces an Infra-Red (IR) signature or the IR footprint of the device, and/or which otherwise reduces visibility or detection of the device by thermal imagers and/or IR-based imagers and/or other types of imagers and/or by human observers.

In accordance with some embodiments, the Specific Weight of the entire rollable and flexible PV article is less than 1.00, thus making the PV article self-buoyant or self-floating on water.

In some embodiments, the Specific Weight of the entire rollable and flexible PV article is less than 1.020 or less than 1.025 or less than 1.030, thus making the PV article self-buoyant or self-floating on most types of sea-water.

In some embodiments, a rolled PV article is capable of generating at least 1,000 Watts of electricity (or, at least 1,800 Watts; or, at least 3,600 Watts), and its un-rolled length is over 3 meters, and its un-rolled area is over 3 meter squared; and such PV article can be transported in a rolled form, and can be deployed on site by unrolling it there. In some embodiments, the PV article further includes only one electrical terminal (wire cable) per each polarity (negative, positive), located less than 1 meter from one end of the long dimension of the PV article. In other embodiments, the PV article includes two electrical terminals (wires/cables), one at each side of the long dimension of the PV article

In some embodiments, an electricity generating system includes said PV article and also a dedicated deployment carrier, such as a suitable wagon or transportation device or vehicle, configured to carry and transport the PV article to the desired deployment site and to unroll there the PV article; and optionally also configured to roll or re-roll the PV article (e.g., for its removal from that site and/or its transport to another site). In some embodiments, the deployment mechanism may include a pulling unit, a pushing unit, a rolling unit, an in-rolling unit, a folding unit, an un-folding unit, or a combination of such units to enable efficient rolling and un-rolling. In some embodiments, the deployment carrier is also configured to perform maintenance operation on the rollable PV article, and/or to re-roll it after deployment, and/or to perform maintenance tasks (e.g., cleaning), and/or to remove the panels/rolls from the site for other maintenance procedures (e.g., replacing a defective part of the PV article).

In some embodiments, the rollable and flexible PV article, once deployed over a body of water and being self-floating thereon, intentionally has a generally non-stable non-fixed nature or position, thus making it uncomfortable or less comfortable for at least some types of birds to stand on and/or to rest on and/or to nest on; and thus accumulating less bird droppings and/or less obstructions to sunlight, and avoiding or reducing degradation of energy harvesting performance.

In some embodiments, the low profile or thin profile of the PV article in its unrolled deployed state, further makes it less attractive as a resting place for at least some types of birds, which may prefer to rest on a taller nearby structure and not on the PV article; thus accumulating less bird droppings and/or less obstructions to sunlight, and avoiding or reducing degradation of energy harvesting performance.

In some embodiments, optionally, the PV article or portions or regions thereof (e.g., its borders or margins or corners; or thin lines or rows or columns among the plurality of solar cells) are coated or sprayed or treated with a material or substance that some animals (e.g., birds, pests, rats) dislike; thus accumulating less bird droppings or animal droppings, and/or less obstructions to sunlight, and avoiding or reducing degradation of energy harvesting performance.

In some embodiments, optionally, the PV article or at least a lower layer or bottom layer thereof, such as the bottom surface or bottom region of the floating medium, and/or other layer(s) or surface(s) or side(s) or edge(s) (e.g., a side surface), that are covered or coated with an anti-fouling material and/or anti-sticking material and/or non-stick material and/or a material that reduces or prevents accumulation of algae.

In accordance with some embodiments, due to the intimate and wide surface that is in touch with the water, the entire PV article (in its deployed un-rolled state, self-floating over water) is generally tolerant or very tolerant to wind; and can withstand winds of up to 150 kilometers per hour (or even up to 300 kilometers per hour); and such winds do not detach the PV article from the surface of the water. In some embodiments, optionally, a “skirt” element or a border element or a framing element, having a width and/or a height of at least 5 or 10 centimeters, touches the water around the PV article and prevents wind from entering beneath such “skirt” element, even in wavy conditions, is very tolerant to wind, and winds up to 150 km/h (or, in some embodiments, even up to 200 or 250 or 300 km/h) cannot detach the PV article from the surface of the water and cannot make it “fly away” or dragged away.

In some embodiments, the rollable and flexible self-floating PV article may have an open electric circuit voltage of the module that is lower than 25 Volts (Direct Current), or that is lower than 30 or 50 or 60 or 120 Volts DC; such that the self-floating PV article complies with applicable safety regulations. In some embodiments, the PV article has integrated or built-in electrical conduits, which transport the generated electric current to the edge of PV article, where a galvanically isolated circuit is further located and used (e.g., inverter, micro-inverter, isolator), and/or where an electric circuitry interface is located and used for outputting the generated electricity (e.g., for powering an electric device, for charging a rechargeable battery or power cell). Such circuitry or electric components or wires are structured to be generally thin and/or flat, such that they and they do not interfere with the rolling and the un-rolling of the PV article.

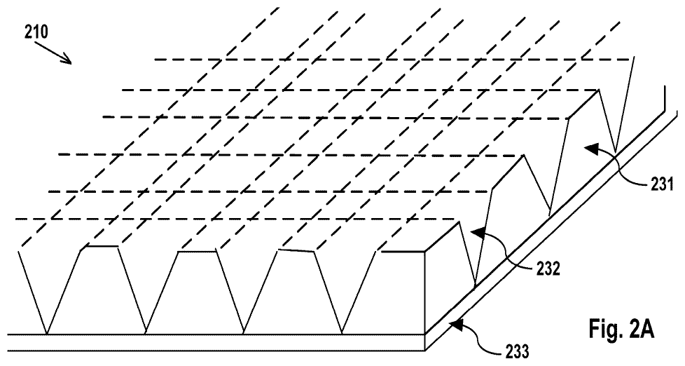

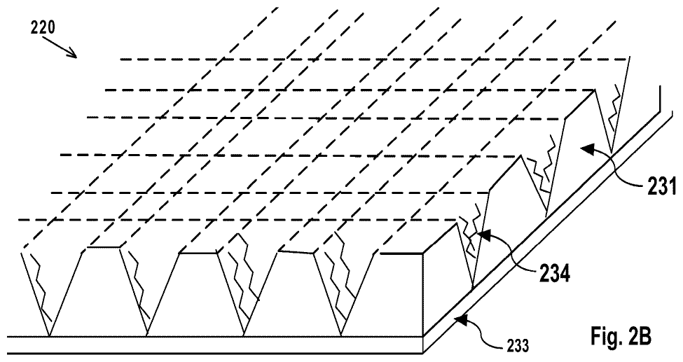

Reference is made to FIGS. 2A and 2B, which are perspective-view illustrations of a rollable and flexible, mechanically resilient, shock absorbing, solar cell (or PV module) 210 and 220 (respectively), in accordance with some demonstrative embodiments. A plurality of such solar cells (210 and/or 220), interconnected to each other electrically and mechanically, may be used as the plurality of solar cells from which the PV article 101 is structured. Each solar cell (210, 220) by itself is rollable and flexible and bendable and foldable; and the arrangement or matrix or array or set of such solar cells (210 and/or 220) is similarly rollable and flexible and bendable and foldable.

The solar cell (210, 220) comprises a single semiconductor wafer 231 (or, a single semiconductor body or substrate), having therein (or, being segmented by) deep craters or grooves or “blind gaps” or non-transcending gaps 232 that penetrate to a depth in the range of 80% to 99.9% of the maximum thickness of the semiconductor wafer 231, and leaving non-penetrated a thin remainder portion 233 of the semiconductor wafer 231 which continues to connect mechanically connect the sub-regions that are created by such segmentation.

In FIG. 2A, the “blind gaps” or craters or non-transcending gaps 232 are shown, in a non-filled implementation; whereas in FIG. 2B, the “blind gaps” or craters or non-transcending gaps 232 are shown filled (either entirely to the top, or only partially) with a filler material 234 which further contributes to the capability of the solar cell (220) to absorb and/or dissipate mechanical shocks and/or mechanical forces, and/or with other filler material(s) which provide or increase thermal durability and/or mechanical durability and/or physical durability and/or mechanical durability and/or mechanical resilience and/or physical resilience and/or chemical resilience and/or thermal resilience.

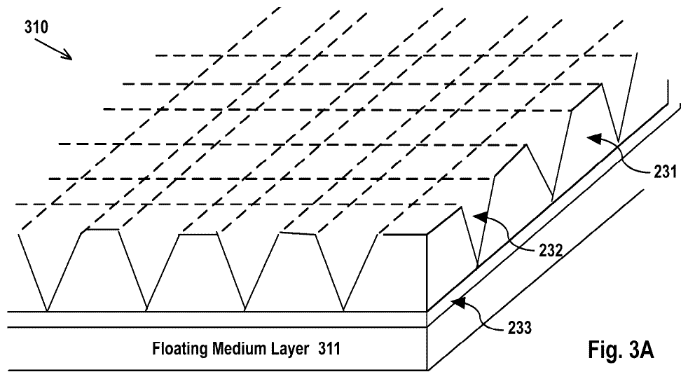

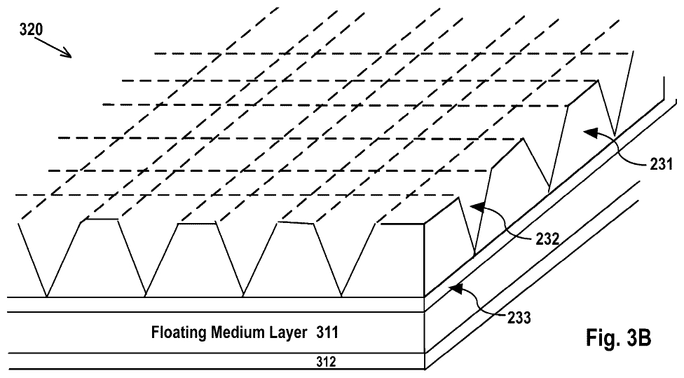

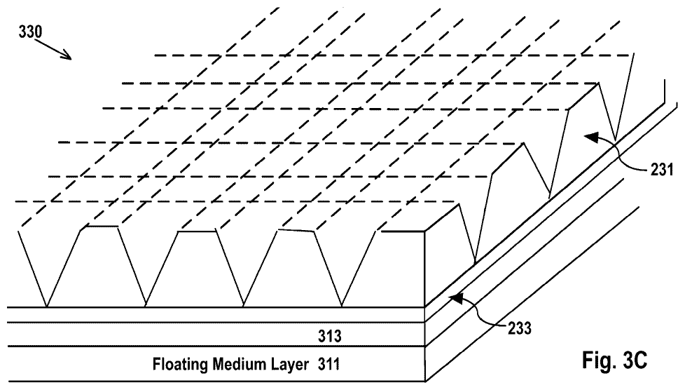

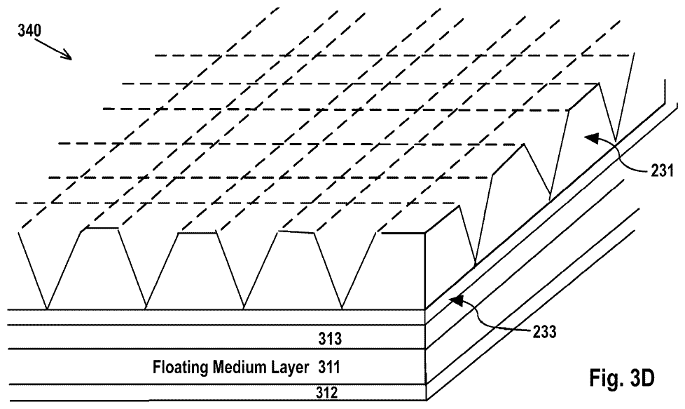

Reference is made to FIG. 3A, which is a perspective-view illustration of a rollable and flexible, mechanically resilient, shock absorbing, PV article 310, in accordance with some demonstrative embodiments. PV article 310 is structured from a generally flat or generally planar array or matrix of solar cells that are electrically inter-connected; each such solar cell is, by itself, an operable, rollable and flexible, bendable and mechanically-resilient and shock-absorbing solar cell, such as solar cell 210 and/or solar cell 220 described above. The array of such solar cells is mechanically connected on to of, or glued or attached on top of, or non-detachably attached on top of, a floating medium layer 311; such as, formed of a lightweight and low-density foam layer or foam material or foamed plastic material(s). The entire operable PV device, namely, the entire PV article 310 that connected or glued or attached on top of the floating medium layer 311, has self-floatation capability or self-buoyancy, and will float on water and will not sink in water.

Reference is made to FIG. 3B, which is a perspective-view illustration of a rollable and flexible, mechanically resilient, shock absorbing, PV article 320, in accordance with some demonstrative embodiments. PV article 320 is generally similar to PV article 310 described above; however, PV article 320 further includes an attached (e.g., glued, mechanically connected, directly touching) bottom-side support layer 312, which may be formed of fabric or woven fabric or non-woven fabric or other suitable material(s), and which is connected or attached or glued beneath the floating medium layer 311. The support layer 312 is similarly rollable and flexible, and it provides tension bearing support or mechanical support to the entirety of the PV article 320. The support layer 312 may be a woven or non-woven fabric or net or layer, which may be formed of polypropylene (PP), thermoplastic polymer(s), polyamide, polyimide, aramid, polyethylene terephthalate (PET), glass, carbon, and/or other material(s).

Reference is made to FIG. 3C, which is a perspective-view illustration of a rollable and flexible, mechanically resilient, shock absorbing, PV article 330, in accordance with some demonstrative embodiments. PV article 330 is generally similar to PV article 310 described above; however, PV article 330 further includes an attached (e.g., glued, mechanically connected, directly touching) central support layer 313, which may be formed of fabric or woven fabric or non-woven fabric or other suitable material(s), and which is connected or attached or glued above the floating medium layer 311 and beneath the bottom-side of the solar cell array. The support layer 313 is similarly rollable and flexible, and it provides tension bearing support or mechanical support to the entirety of the PV article 330. The support layer 313 may be a woven or non-woven fabric or net or layer, which may be formed of polypropylene (PP), thermoplastic polymer(s), polyamide, polyimide, aramid, polyethylene terephthalate (PET), glass, carbon, and/or other material(s).

Reference is made to FIG. 3D, which is a perspective-view illustration of a rollable and flexible, mechanically resilient, shock absorbing, PV article 340, in accordance with some demonstrative embodiments. PV article 340 is generally similar to PV article 310 described above; however, PV article 330 further includes: (i) an attached (e.g., glued, mechanically connected, directly touching) central support layer 313, which may be formed of fabric or woven fabric or non-woven fabric or other suitable material(s), and which is connected or attached or glued above the floating medium layer 311 and beneath the bottom-side of the solar cell array; and also, (ii) an attached (e.g., glued, mechanically connected, directly touching) bottom-side support layer 312, which may be formed of fabric or woven fabric or non-woven fabric or other suitable material(s), and which is connected or attached or glued beneath the floating medium layer 311. Each of the support layers (312, 313) is similarly rollable and flexible, and provides tension bearing support or mechanical support to the entirety of the PV article 340.

The examples shown in FIGS. 3A-3D are non-limiting; and some embodiments may include other combinations or arrangements of floating medium layer(s) and optionally also support layers. For example, in some embodiments, two or more floating medium layers may be used, with a support layer sandwiched between them. Other stacking arrangements may be used.

Similarly, for demonstrative purposes, the examples shown in FIGS. 3A-3D show the “blind gaps” or non-transcending gaps or craters, without storing or having therein any filler material(s); however, in some embodiments, the “blind gaps” or non-transcending gaps or craters in the semiconductor wafer contain or store or have therein one or more filler material(s).

In some embodiments, the craters or “blind gaps” or non-transcending gaps in the semiconductor wafer or semiconductor substrate, provide to each solar cell enhanced properties of mechanical resilience and/or mechanical shock absorption and/or mechanical force absorption and/or mechanical shock dissipation and/or mechanical forces dissipation. For example, a mechanical shock or force, such as rolling or bending, may propagate and also dissipate along the rows or columns of such non-transcending gaps, and/or may be absorbed across a plurality of neighboring craters or non-transcending gaps (e.g., those that neighbor or surround a point-of-impact at which the force was applied or the shock has occurred); optionally causing slight movement or relative motion of some sub-regions of the solar cell as they absorb or propagate and dissipate the mechanical shock or force; while also preventing breakage or cracking of the solar panel, and while keeping operable and intact.

In some embodiments, some, or a majority of, or all, of the craters or the “blind gaps” or the non-transcending gaps, may be include therein a gap filler material, or a combination or mixture of filler materials. The gap filler may be at least partially composed of a material possessing properties of mechanical force or mechanical shock absorption or dissipation, compressibility and/or stretch-ability and/or flexibility and/or mechanical resilience increasing properties, and/or thermal absorption and/or thermal dissipation properties. In some embodiments, the gap filler may be at least partially composed of a material having electrically insulative properties.

In some embodiments, the gap filler may be reactively grown within a respective non-transcending gap; or may be deposited within or added into such non-transcending gap. A gap filler may form a coating over sidewalls of a non-transcending gap. A gap filler may form a coating over shoulders of sidewalls of a non-transcending gap, and may optionally form a continuous layer at the level of said shoulders. In some embodiments, optionally, a gap filler may be transparent or translucent, or may allow passage there-through of at least 75 (or 80, or 90) percent of light.

The gap filler according to some embodiments may be composed of at least one material selected from the group consisting of: (a) a polymer; (b) a resin, (c) amorphous silicon; (d) glass; (e) a metal; (f) carbon; (g) oxygen; (h) a monomer; (i) a second semiconductor; (j) an oligomer; (k) a reactive system (e.g. monomer and photo-initiator); (1) ethylene vinyl acetate (EVA); (m) polyvinylidene fluoride (PVDF); (n) Silicone; and (o) a combination of 2 or more of the above. The gap filler may be homogeneous; or, may be a heterogeneous filler system comprised of at least one matrix material (e.g., a polymer) and at least one additive (e.g., discrete domains of a second, softer polymer or other material).

In some embodiments, a gap filler may be reactively produced inside of a non-transcending gap. For example, a reactive chemical (e.g., oxygen, ammonia) may be introduced during (and/or after) laser cutting or laser etching or chemical etching that produces the non-transcending gap (e.g., while, or after, such process causes removal of a portion of the semiconductor wafer or substrate), and a reaction between the reactive chemical and material of the gap's sidewalls (namely, the semiconductor wafer or substrate) may form a coating on such sidewalls. The coating may be of a uniform thickness, or may have varying non-uniform thickness; and in some cases may mechanically expand to slightly push apart the sidewalls of the non-transcending gap. In other embodiments, a reactive mixture of chemicals may be introduced into an already placed or produced non-transcending gap; and the reactive mixture may be allowed to react within the non-transcending gap, thereby filling the gap with a product of the reaction, which may physically push apart the sidewalls of the non-transcending gap.

According to further embodiments, a gap filler may include a set of materials deposited as one or more discrete layers within or across such non-transcending gap. Different layers of the deposited discrete layers may have different properties, and may serve or may provide different functionalities, for example, mechanical shock absorption or dissipation, mechanical forces absorption or dissipation, mechanical resilience, thermal resilience, physical resilience, electrical insulation, and/or other functionalities.

In some embodiments, the gap filler material(s) may optionally include a polymer/oligomer/monomer system for mechanical resilience, such as ethylene vinyl acetate (EVA), high-impact polystyrene (HIPS), thermoplastic elastomers (TPEs), block copolymers of polystyrene-polybutadiene and/or polystyrene-polyisoprene (diblock, triblock, multiblock, and/or random co-polymers), polybutadiene neoprene, ethylene propylene diene monomer (EPDM) synthetic rubber, natural elastomers, synthetic elastomers, and/or flexible materials or stretch-able materials.

In some embodiments, the gap filler material(s) may be used for heat and/or electrical conductivity; for example, using or including carbon fibers, metallic powders, metallic nano-particles, metallic nano-fibers, metallic fillings and/or metallic fibers; including (but not limited to) iron, copper, silver, aluminum, and/or mixtures and/or alloys of the above materials; which may optionally be distributed in a polymeric, ceramic, or other matrix or in conductive polymers, Carbon Nanotubes (CNT)s, Graphene, and/or other materials.

In some embodiments, gap filler being or having reactive mixtures that swell or expand upon reaction may include, for example, a poly-isocyanate and/or a polyol, with the presence or water or without the presence of water, to produce a foamed polyurethane. Alternatively, blowing agents may be used or incorporated, such as azodicarbonamide, to create ad hoc foam within the non-transcending gap, resulting in expansion of the material within the non-transcending gaps and an increase in volume that will increase the width of the non-transcending gap.

In some embodiments, at least part of the gap filler material may be an anisotropic material. For example, anisotropic particles of fibers may be affixed in a specific direction relative to the top or bottom surface of the body matrix, as well as conductive polymers, CNTs, or Graphene, suspended within a binding material such as a polymer. Anisotropic particles or micro-fibers may be aligned, in one direction or another relative to a top or bottom surface or a different specific plane in the substrate, prior to curing of the gap filler material, by using a magnetic or an electric field. Such mixture may contribute to the mechanical, physical and/or thermal resilience of the remaining semiconductor wafer or substrate and of the entirety of the solar cell and PV article. Particles, isotropic or anisotropic in nature, may be included below or above the percolation threshold.

In some embodiments, a gap filler material which is anisotropic can lend anisotropic characteristics to the semiconductor substrate or wafer. The filler material may contain anisotropic particles (e.g., micro-fibers) that may be aligned or oriented using an external force field, such as a magnetic or electrical field. If these anisotropic particles are embedded in a filler matrix which can be “set” (such as a polymer, monomer or oligomer that can be crosslinked), these properties will remain with a permanent preferred orientation even after turning off the external aligning force field.

In some embodiments, each of the solar cells is rollable and flexible by itself; and is a single PV device or is a single PV article, that is comprised of a single semiconductor substrate or a single semiconductor wafer or a single semiconductor body; which is monolithic, e.g., is currently, and has been, a single item or a single article or a single component that was formed as (and remained) a single component; such that each solar cell is not formed as a collection or two or more separate units or as a collection of two or more entirely-separated or entirely-discrete or entirely-gapped units that were arranged or placed together in proximity to each other yet onto a metal foil or onto a metal film or onto a flexible or elastic foil or film.

In some embodiments, each single solar cell that is flexible and rollable by itself, is not a collection and is not an arrangement and is not an assembly of multiple discrete solar cells of PV modules, that each one of them has its own discrete and fully separated semiconductor substrate and/or its own discrete and fully separated semiconductor wafer and/or its own discrete and fully separated semiconductor body, and that have been merely placed to assembled or arranged together (or mounted together, or connected together) onto or beneath a flexible foil or a flexible film; but rather, the each single solar cell has a single unified semiconductor substrate or semiconductor body or semiconductor wafer that is common to, and is shared by, all the sub-regions or areas or portions of that single solar cell which includes therein (in that unified single semiconductor substrate or wafer or body) those non-transcending craters or non-transcending gaps or “blind gaps” that penetrate only from one side (and not from both sides), which do not reach all the way through and do not reach all the way to the other side of the unified single semiconductor substrate or wafer or body.

In some embodiments, each solar cell may be, or may include, a mono-crystalline PV cell or solar panel or solar cell, a poly-crystalline PV cell or solar panel or solar cell, a flexible PV cell or solar cell that is an Interdigitated Back Contact (IBC) solar cell having said semiconductor wafer with said set of non-transcending gaps, and/or other suitable type of PV cell or solar cell.

Some portions of the discussion above and/or herein may relate to regions or segments or areas, of the semiconductor body or substrate or wafer (or PV cell, or PV device); yet those “segments” are still touching each other and/or inherently connected to each other and/or non-separated from each other, as those “segments” are still connected by at least a thin portion or a thin bottom-side surface of the semiconductor substrate (or wafer, or body), which still holds and includes at least 1 (or at least 2, or at least 3, or at least 5, or at least 10, or at least 15, or at least 20, or at least 25, or at least 33; but not more than 50, or not more than 40) percent of the entire depth or the entire thickness (or the maximum thickness or depth) of the semiconductor substrate or body or wafer; as those “segments” are still connected at their base through such thin layer, and those “segments” have between them (or among them) the non-transcending gaps or the “blind gaps” or the non-transcending craters that thus separate those “segments” but that do not fully divide or fully break or fully isolate any two such neighboring “segments” from each other. Upon its production, and prior to attaching the solar cells onto the floating medium layer, each such flexible and rollable solar cell is freestanding and carrier-less and non-supported.

In some embodiments, the non-transcending gaps or the “blind gaps” or craters or slits or grooves, are introduced and are formed only at a first side or at a first surface of the semiconductor substrate or body or wafer, and are not formed at both of the opposite surfaces (or sides) thereof.

In some embodiments, the non-transcending gaps or the “blind gaps” or craters or slits or grooves, are introduced and are formed only at a first side or at a first surface of the semiconductor substrate or body or wafer, that is intended to face the sunlight or the light, or that is the active side of the PV device or PV cell, or that is intended to be the active side of the PV device or PV cell, or that is intended to be the electricity-generating side or surface that would generated electricity based on incoming sunlight or light or based on the PV effect; and they are not formed at the other (e.g., opposite, non-active) side or surface (e.g., the side that is not intended to be facing the sunlight or the light, or the side that is not intended to be producing electricity based on the PV effect).

In other embodiments, the non-transcending gaps or the “blind gaps” or craters or slits or grooves, are not introduced and are not formed at the side or surface of the semiconductor substrate or body or wafer, that is intended to face the sunlight or the light, or that is the active side of the PV device or PV cell, or that is intended to be the active side of the PV device or PV cell, or that is intended to be the electricity-generating side or surface that would generated electricity based on incoming sunlight or light or based on the PV effect; but rather, those non-transcending gaps or the “blind gaps” or craters or slits or grooves are formed at the other (e.g., opposite, non-active) side or surface, which is the side that is not intended to be facing the sunlight or the light, or the side that is not intended to be producing electricity based on the PV effect. Some implementations with this structure may advantageously provide the mechanical shock absorption and the mechanical forces dissipation capability, yet may also provide or maintain or achieve an increased level of PV-based electricity production since the gaps do not reduce the area of the light-exposed side or the light-facing side of the PV device.

In still other embodiments, the non-transcending gaps or the “blind gaps” or craters or slits or grooves, are introduced and are formed at both sides or at both surfaces of the semiconductor substrate or body or wafer; yet with an offset among the gaps of the first side and the gaps of the second side, in a zig-zag pattern of those gaps which zig-zag across the two sides of the semiconductor wafer or substrate or body; for example, a first gap located at the top surface on the left; then, a second gap located at the bottom surface to the right side of the first gap and not overlapping at all with the first gap; then, a third gap located at the top surface to the right side of the second gap and not overlapping at all with the second gap; then, a fourth gap located at the bottom surface to the right side of the third gap and not overlapping at all with the third gap; and so forth. In such structure, for example, any single point or any single location or any single region of the remaining semiconductor wafer or substrate or wafer, may have a gap or a crater or a “blind gap” only on one of its two sides, but not on both of its sides.

In yet other embodiments, the non-transcending gaps or the “blind gaps” or craters or slits or grooves, are introduced and are formed at both sides or at both surfaces of the semiconductor substrate or body or wafer; not necessarily with an offset among the gaps of the first side and the gaps of the second side, and not necessarily in a zig-zag pattern; but rather, by implementing any other suitable structure or pattern that still provides the mechanical shock resilience, and while also maintaining a sufficiently-thin layer of semiconductor substrate or body or wafer that is not removed and that is resilient to mechanical shocks and mechanical forces due to the craters or gaps that surround it.

Some embodiments may include and/or may utilize one or more units, devices, connectors, wires, electrodes, and/or methods which are described in United States patent application publication number US 2016/0308155 A1, which is hereby incorporated by reference in its entirety. For example, some embodiments may include and may utilize an electrode arrangement which is configured to define or create a plurality of electricity collection regions, such that within each of the collection regions, at least two sets of conducting wires are provided such that they are insulated from each other, and the at least two sets of conducting wires are connected either in parallel or in series between the collection regions to thus provide accumulating voltage of charge collection. Some embodiments may include an electric circuit for reading-out or collection or aggregation of the generated electricity, configured as an electrodes arrangement, including conducting wires arranged in the form of nets covering zones of a pre-determined area. The electrodes arrangement may be configured or structured to be stretched (e.g., rolled out) along the surface of the PV cell, and may be formed by at least two sets of conducting wires, and may cover a plurality of collection zones or collection regions.

Within each of the electricity collection zones or electricity aggregation zones, the different conducting wires are insulated from each other, to provide a certain voltage between them. At a transition between zones, the negative charges collecting conductive wire of one zone, is electrically connected to the positive charges collecting conductive wire of the adjacent or the consecutive zone. Thus, within each of the collection zones, the different sets of conducting wires are insulated from each other, while being connected in series between the zones. This configuration of the electrode arrangement allows accumulation or aggregation of electric voltage generated by charge collection along the surface of the PV device. The configuration of the electrode arrangement provides a robust electric collection structure.

The internal connections between the sets of conducting wires allow energy collection even if the surface being covered is not continuous, e.g., if a perforation occurs in the structure of the net. This feature of the electrode arrangement allows for using this technique on any surface exposed to photon radiation, while also allowing discontinuity if needed and without limiting or disrupting the electric charge collection.

In some embodiments, a set of conducting wires may be embedded in or within a flexible and/or adhesive and/or transparent-to-light plastic foil or plastic film or encapsulant, is embedded immediately beneath such film or foil or encapsulant, or immediately over such film or foil or encapsulant, or is included within such film or foil or encapsulant (e.g., such that the plastic or encapsulant is to the right and to the left of each conducting wire but does not obstruct and does not prevent the conducting wire from touching the solar cell surface for collecting electric charge therefrom). In some embodiments, the sunny-side surface and/or the dark-side surface of each solar cell, or the top-side and/or the bottom-side of each solar cell, may be coated with an adhesive or a transparent adhesive and/or with an electrically-conducting adhesive and/or an electrically-conducting transparent adhesive, to enable gluing or bonding of such surface of the PV cell to the set of conducting wires, for long-term bonding or at least for short-term bonding during the production process before the plastic foil is heated and/or before the PV cell is laminated or encapsulated.

In some embodiments, some, or all, or a majority of, the non-transcending craters or “blind gaps”, are filled with one or more filler material(s), which further provide mechanical shock absorption and/or mechanical shock dissipation and/or thermal resilience and/or mechanical resilience and/or physical resilience and/or chemical resilience and/or mechanical durability and/or thermal durability and/or physical durability and/or chemical durability.

In some embodiments, each of the solar cells in the array, and/or the entirety of the array of solar cells, is laminated and/or encapsulated, within a single lamination layer or a single encapsulation layer, or within two or more layers or coatings or encapsulants, which may be transparent and enable light to pass there-through, or which may be translucent and may enable at least 75% of light to pass there-through, and which may provide further mechanical resilience and damage protection to the solar cells and their array.

In some embodiments, a device comprises a self-floating, rollable, flexible, photovoltaic article, that is formed of a plurality of flexible and rollable and mechanically-resilient solar cells that are inter-connected as a generally planar (yet flexible and rollable) array. Each of said flexible and rollable and mechanically-resilient solar cells has (I) a sunny-side or top-side surface that is configured to absorb light, and (II) a back-side or or bottom-side surface that is opposite to said sunny-side surface and is not necessarily configured to absorb light (e.g., in some implementations it does not absorb light and it is a “dark side”; or, in other implementations, it also absorbs light and it is a “sunny side”). Each of said flexible and rollable and mechanically-resilient solar cells is configured to generate electric current from light via the photovoltaic effect. The generally-planar array of flexible and rollable and mechanically-resilient solar cells, is bonded or glued or attached to, or is non-detachably attached to, or is encapsulated within, a polymeric and/or foamed layer or encapsulation layer or coating or encapsulation layers or support layers or foamed layers or low-density layer(s) or low-Specific-Weight layer(s), which may be beneath the solar cells and/or within the solar cells and/or covering on top of the solar cells (e.g., being transparent or translucent) and/or bonded to one or more sides or borders of the solar cells, such that the overall Specific Weight of the device is smaller than 1.00 and thus the device is self-buoyant or self-floating over water.

In some embodiments, additionally or alternatively, a low-density (or reduced-density, or foamed polymers) rollable and flexible layer, such as foamed polymer(s), is bonded and/or glued and/or non-detachably attached and/or non-removably attached and/or integrally attached beneath the bottom side or beneath the lowest surface of the photovoltaic article, and provides a self-buoyancy property to the entirety of the photovoltaic article; such that the overall Specific Weight of the device is smaller than 1.00 and thus the device is self-buoyant or self-floating over water.

In some embodiments, additionally or alternatively, a low-density (or reduced-density, or foamed polymers) rollable and flexible layer, such as foamed polymer(s), is bonded and/or glued and/or non-detachably attached and/or integrally attached and/or non-removably attached at a side (e.g., right side and/or left side) of the photovoltaic article, and provides a self-buoyancy property to the entirety of the photovoltaic article; such that the overall Specific Weight of the device is smaller than 1.00 and thus the device is self-buoyant or self-floating over water.

In some embodiments, additionally or alternatively, a low-density rollable and flexible layer, such as foamed polymer(s), is bonded and/or glued and/or non-detachably attached and/or integrally attached and/or non-removably internally attached (or sandwiched, or encapsulated) within two of the already-existing layers of the solar cells (e.g., at one or more suitable locations between the top-most surface of the solar cells and the lowest surface of the solar cells), and/or is entirely or at least partially encapsulated or sandwiched within other layers of the solar cells, and provides a self-buoyancy property to the entirety of the photovoltaic article; such that the overall Specific Weight of the device is smaller than 1.00 and thus the device is self-buoyant or self-floating over water.

In some embodiments, additionally or alternatively, a low-density (or reduced-density, or foamed polymers) rollable and flexible layer, such as foamed polymer(s), is bonded and/or glued and/or non-detachably attached and/or integrally attached and/or non-removably attached on top of the top-most surface or upper-most surface of the solar cells, and may be transparent or translucent (e.g., allowing full or at least partial of light there-through), and provides a self-buoyancy property to the entirety of the photovoltaic article; such that the overall Specific Weight of the device is smaller than 1.00 and thus the device is self-buoyant or self-floating over water.

In some embodiments, additionally or alternatively, a low-density rollable and flexible layer, such as foamed polymer(s), is bonded and/or glued and/or non-detachably attached and/or non-removably attached on top of the top-most surface or upper-most surface of the solar cells, and may be transparent or translucent (e.g., allowing full or at least partial of light there-through), and provides a self-buoyancy property to the entirety of the photovoltaic article; such that the overall Specific Weight of the device is smaller than 1.00 and thus the device is self-buoyant or self-floating over water.

Some embodiments may utilize and/or may include components, structures, devices, methods, systems and/or techniques that are described in PCT international application number PCT/IL2021/051202, having an international filing date of Oct. 8, 2021, which is hereby incorporated by reference in its entirety.

Some embodiments may utilize and/or may include components, structures, devices, methods, systems and/or techniques that are described in PCT international application number PCT/IL2021/051269, having an international filing date of Oct. 27, 2021, which is hereby incorporated by reference in its entirety.

Some embodiments may utilize and/or may include components, structures, devices, methods, systems and/or techniques that are described in PCT international application number PCT/IL2022/050030, having an international filing date of Jan. 10, 2022, which is hereby incorporated by reference in its entirety.

Some embodiments may utilize and/or may include components, structures, devices, methods, systems and/or techniques that are described in patent application U.S. Ser. No. 17/353,867, filed on Jun. 22, 2021, published as US 2021/0313478, which is hereby incorporated by reference in its entirety.

Some embodiments may utilize and/or may include components, structures, devices, methods, systems and/or techniques that are described in patent number U.S. Pat. No. 11,081,606 B2, which is hereby incorporated by reference in its entirety.

In some embodiments a device comprises (or is) a self-floating, rollable, flexible, photovoltaic article; that is formed of a plurality of flexible and rollable and mechanically-resilient solar cells that are inter-connected as a generally planar array. Each of said flexible and rollable and mechanically-resilient solar cells has (I) a sunny-side surface that is configured to absorb light, and (II) a bottom-side (or back-side, or lower-side) surface that is opposite to said sunny-side surface and is not necessarily configured to absorb light. Each of said flexible and rollable and mechanically-resilient solar cells is configured to generate electric current from light via the photovoltaic effect. The generally planar array of flexible and rollable and mechanically-resilient solar cells, is at least one of: (i) non-detachably and integrally encapsulated within a multi-layer polymeric buoyancy-providing encapsulation structure that provides self-buoyancy property to the entirety of said photovoltaic article; (ii) non-detachably and integrally attached to one or more low-density buoyancy-providing layers that provide self-buoyancy property to the entirety of said photovoltaic article; (iii) non-detachably and integrally contains therein one or more low-density buoyancy-providing layers that provide self-buoyancy property to the entirety of said photovoltaic article; or is a combination of two of the above, or of all three of the above. The overall Specific Weight of the entirety of said photovoltaic article is smaller than 1.00.

In some embodiments, the device is capable of autonomously floating on water, without requiring to be mounted onto a raft or boat or detachable floatation device, due to said flexible and rollable solar cells being integrally and non-removably attached to one or more self-buoyant low-density rollable and flexible floating-capability layers.

In some embodiments, at least one of the layers of the photovoltaic article, that is an integral and non-removable part of the photovoltaic article, is made of low-density rollable and flexible foamed polymer that provides self-buoyancy property to the entirety of said photovoltaic article.

In some embodiments, the one or more low-density rollable and flexible foamed layers are formed of one or more materials selected from the group consisting of: (i) foamed polyethylene, (ii) foamed polypropylene, (iii) foamed polyurethane.

In some embodiments, the one or more self-buoyant low-density rollable and flexible floating-capability layers comprise at least a layer of foamed polymer having closed-cell pores.

In some embodiments, the one or more self-buoyant low-density rollable and flexible floating-capability layers comprises at least a layer of foamed polymer; wherein a top-side surface of said foamed polymer is a solidified previously-molten surface of foamed polymer that had been molten and brought into contact with the dark-side surface of said solar cells and that integrally attached to the bottom-side surface of said solar cells; wherein a bottom-side side surface of said solar cells, and the rollable and flexible floating-capability layer which is formed of foamed polymer, are integrally and mechanically attached to each other via said solidified previously-molten surface of foamed polymer.

In some embodiments, the one or more self-buoyant low-density rollable and flexible floating-capability layers comprise at least a layer of foamed polymer that is non-detachably bonded to a bottom-surface of the bottom-side surface of said solar cells.

In some embodiments, the device further comprises: a bottom-side tension bearing layer, which is rollable and flexible, and which is attached to a bottom side of the rollable and flexible floating-capability layer; wherein the bottom-side tension bearing layer provides mechanical support and tension bearing and mechanical integrity to said device.

In some embodiments, the device further comprises: a central, sandwiched, tension bearing layer, which is rollable and flexible, and which is attached and is sandwiched between (i) a top side of the rollable and flexible floating-capability layer, and (ii) a bottom side of the bottom-side surface of said solar cells; wherein the central, sandwiched, tension bearing layer provides mechanical support and tension bearing and mechanical integrity to said device.

In some embodiments, the device further comprises: a bottom-side tension bearing layer, which is rollable and flexible, and which is attached to a bottom side of the rollable and flexible floating-capability layer; wherein the bottom-side tension bearing layer provides mechanical support and tension bearing and mechanical integrity to said device; and also, (II) a central, sandwiched, tension bearing layer, which is rollable and flexible, and which is attached and is sandwiched between (i) a top side of the rollable and flexible floating-capability layer, and (ii) a bottom side of the bottom-side surface of said solar cells; wherein the central, sandwiched, tension bearing layer provides mechanical support and tension bearing and mechanical integrity to said device.

In some embodiments, at least one of (i) the bottom-side tension bearing layer, and (ii) the central, sandwiched, tension bearing layer, is a woven fabric that is formed of one or more materials selected from the group consisting of: polypropylene (PP), thermoplastic polymer(s), polyamide, polyimide, aramid, polyethylene terephthalate (PET), glass.

In some embodiments, at least one of (i) the bottom-side tension bearing layer, and (ii) the central, sandwiched, tension bearing layer, is a non-woven fabric that is formed of one or more materials selected from the group consisting of: polypropylene (PP), thermoplastic polymer(s), polyamide, polyimide, aramid, polyethylene terephthalate (PET), glass.

In some embodiments, any of the above-mentioned tension bearing layer(s) has a low density or a Specific Weight that is smaller than 1.00, in order to contribute to the self-buoyancy property of the entirety of the PV article or device, and/or in order to provide or increase the floating capability of the PV article or device while also providing tension-bearing capability.

In some embodiments, at least a portion of a top surface of the device is coated with a bird repellant or an animal repellant.

In some embodiments, at least a portion of a surface (e.g., bottom surface, top surface, side surface) of the device is coated with a material that reduces or prevents formation of algae.

In some embodiments, at least a portion of a bottom surface of the device is coated with a non-stick material that reduces or prevents attachment of objects to a bottom side of the device.

In some embodiments, at least a portion of a top surface of the device is coated with translucent paint, which provides a camouflage to said device relative to its surrounding, and also enables passage of at least 75% of light through said translucent paint.

In some embodiments, at least a portion of a top surface of the device is coated with translucent paint or coating or layer, which reduces an Infra-Red (IR) signature of the device.

In some embodiments, the device further comprises: a wind-blocking element that surrounds at least a border frame of said device, and prevents wind from entering into a region of contact between the device and a body of water, and prevents wind from causing said device to fly away or to be dragged away.

In some embodiments, the device is an autonomously-floating electricity-generating swimming pool cover.

In some embodiments, each of said solar cells is formed of a single semiconductor wafer having a plurality of non-transcending craters, that penetrate upwardly from the dark-side surface towards the sunny-side surface but do not reach said sunny-side surface; wherein said non-transcending craters penetrate upwardly into between 80 to 99.9 percent of a height of said semiconductor wafer, and segment said semiconductor wafer into a plurality of miniature sub-regions; wherein each sub-region has a surface area or a footprint area, measured at the sunny-side surface of the solar cell, in a range of 0.1 to 500 square-millimeters; wherein said plurality of non-transcending craters and said plurality of miniature sub-regions causes said solar cell to have improved properties of mechanical resilience and mechanical shock absorption and mechanical shock dissipation.

In some embodiments, said non-transcending craters do not store and do not include therein any filler material; said non-transcending craters increase mechanical resilience and mechanical shock absorption and shock dissipation, of each said solar cell, due to existence of a plurality of said non-transcending craters that are arranged in rows and columns and that collectively absorb and dissipate mechanical forces and mechanical shocks.

In some embodiments, said non-transcending craters store and include therein a filler material, which provides mechanical resilience and mechanical shock absorption and shock dissipation to each of said solar cells.

In some embodiments, each of said solar cells is a stand-alone flexible thin-film solar panel.

Some embodiments include a method of producing the device described above, the method comprising: (a) producing the plurality of flexible and rollable and mechanically-resilient solar cells that are inter-connected as said generally planar array; (b) producing the self-buoyant low-density rollable and flexible floating-capability layer; (c) integrally attaching and non-removably connecting, via a non-detachable connection mechanism, (i) the plurality of flexible and rollable and mechanically-resilient solar cells, on top of (ii) the self-buoyant low-density rollable and flexible floating-capability layer; wherein an overall Specific Weight of the entirety of said photovoltaic article is smaller than 1.00.

In some embodiments, a photovoltaic article comprises: (a) a plurality of flexible and rollable and mechanically-resilient solar cells that are inter-connected as a generally planar array that is also flexible and rollable; (b) a self-buoyant low-density rollable and flexible floating-capability providing layer, that is integrally attached and is non-removably connected, via a non-detachable connection mechanism, to a bottom side of said generally planar array of flexible and rollable solar cells; wherein an overall Specific Weight of an entirety of said photovoltaic article is smaller than 1.00.

In some embodiments, a photovoltaic article comprises: (a) a plurality of flexible and rollable and mechanically-resilient solar cells that are inter-connected as a generally planar array that is also flexible and rollable; (b) a self-buoyant low-density rollable and flexible floating-capability providing layer, that is integrally attached and is non-removably connected, via a non-detachable connection mechanism, as a sandwiched layer within said flexible and rollable solar cells; wherein an overall Specific Weight of an entirety of said photovoltaic article is smaller than 1.00.

In some embodiments, a photovoltaic article comprises: (a) a plurality of flexible and rollable and mechanically-resilient solar cells that are inter-connected as a generally planar array that is also flexible and rollable; (b) a self-buoyant low-density rollable and flexible floating-capability providing layer, that is transparent or translucent to light, and that is integrally attached and is non-removably connected, via a non-detachable connection mechanism, on top of a sunny side of said flexible and rollable solar cells; wherein an overall Specific Weight of an entirety of said photovoltaic article is smaller than 1.00.

In some embodiments, a photovoltaic article comprises: (a) a plurality of flexible and rollable and mechanically-resilient solar cells that are inter-connected as a generally planar array that is also flexible and rollable; (b) a self-buoyant low-density rollable and flexible floating-capability providing layer, that is integrally attached and is non-removably connected, via a non-detachable connection mechanism, as an encapsulation structure that encapsulates therein said flexible and rollable solar cells; wherein at least a top-side region of said encapsulation structure is transparent or translucent; wherein an overall Specific Weight of an entirety of said photovoltaic article is smaller than 1.00.

In some embodiments, a self-floating, rollable, flexible, photovoltaic article includes: (a) a plurality of flexible and rollable and mechanically-resilient solar cells that are inter-connected as a generally planar array that is also flexible and rollable; and (b) a self-buoyant low-density rollable and flexible floating-capability providing layer, that is integrally attached and is non-removably connected, via a non-detachable connection mechanism, to a bottom side or a top side or the generally planar array of flexible and rollable solar cells, or integrally encapsulates the flexible and rollable solar cells, or is integrally sandwiched within the flexible and rollable solar cells. The overall Specific Weight of an entirety of the photovoltaic article is smaller than 1.00.

The terms “plurality” and “a plurality”, as used herein, include, for example, “multiple” or “two or more”. For example, “a plurality of items” includes two or more items.

References to “one embodiment”, “an embodiment”, “demonstrative embodiment”, “various embodiments”, “some embodiments”, and/or similar terms, may indicate that the embodiment(s) so described may optionally include a particular feature, structure, or characteristic, but not every embodiment necessarily includes the particular feature, structure, or characteristic. Furthermore, repeated use of the phrase “in one embodiment” does not necessarily refer to the same embodiment, although it may. Similarly, repeated use of the phrase “in some embodiments” does not necessarily refer to the same set or group of embodiments, although it may.

As used herein, and unless otherwise specified, the utilization of ordinal adjectives such as “first”, “second”, “third”, “fourth”, and so forth, to describe an item or an object, merely indicates that different instances of such like items or objects are being referred to; and does not intend to imply as if the items or objects so described must be in a particular given sequence, either temporally, spatially, in ranking, or in any other ordering manner.

Functions, operations, components and/or features described herein with reference to one or more embodiments, may be combined with, or may be utilized in combination with, one or more other functions, operations, components and/or features described herein with reference to one or more other embodiments. Some embodiments may thus comprise any possible or suitable combinations, re-arrangements, assembly, re-assembly, or other utilization of some or all of the modules or functions or components that are described herein, even if they are discussed in different locations or different chapters of the above discussion, or even if they are shown across different drawings or multiple drawings.

While certain features of some demonstrative embodiments have been illustrated and described herein, various modifications, substitutions, changes, and equivalents may occur to those skilled in the art. Accordingly, the claims are intended to cover all such modifications, substitutions, changes, and equivalents.

What is claimed is:

1. A device comprising:
a self-floating, rollable, flexible, photovoltaic article,
that is formed of a plurality of flexible and rollable and mechanically-resilient solar cells that are inter-connected as a generally planar array;
wherein each of said flexible and rollable and mechanically-resilient solar cells has (I) a sunny-side surface that is configured to absorb light, and (II) a bottom-side surface that is opposite to said sunny-side surface and is not necessarily configured to absorb light;
wherein each of said flexible and rollable and mechanically-resilient solar cells is configured to generate electric current from light via the photovoltaic effect;
wherein the generally planar array of flexible and rollable and mechanically-resilient solar cells, is at least one of:
(i) non-detachably and integrally encapsulated within a multi-layer polymeric buoyancy-providing encapsulation structure that provides self-buoyancy property to the entirety of said photovoltaic article,
(ii) non-detachably and integrally attached to one or more low-density buoyancy-providing layers that provide self-buoyancy property to the entirety of said photovoltaic article,
(iii) non-detachably and integrally contains therein one or more low-density buoyancy-providing layers that provide self-buoyancy property to the entirety of said photovoltaic article;
wherein an overall Specific Weight of the entirety of said photovoltaic article is smaller than 1.00.

2. The device of claim 1,
wherein the device is capable of autonomously floating on water, without requiring to be mounted onto a raft or boat or detachable floatation device, due to said flexible and rollable solar cells being integrally and non-removably attached to one or more self-buoyant low-density rollable and flexible floating-capability layers.

3. The device of claim 2,
wherein at least one of the layers of the photovoltaic article, that is an integral and non-removable part of the photovoltaic article, is made of low-density rollable and flexible foamed polymer that provides self-buoyancy property to the entirety of said photovoltaic article.

4. The device of claim 2,
wherein the one or more low-density rollable and flexible foamed layers are formed of one or more materials selected from the group consisting of: (i) foamed polyethylene, (ii) foamed polypropylene, (iii) foamed polyurethane.

5. The device of claim 2,
wherein the one or more self-buoyant low-density rollable and flexible floating-capability layers comprise at least a layer of foamed polymer having closed-cell pores.

6. The device of claim 2,
wherein the one or more self-buoyant low-density rollable and flexible floating-capability layers comprises at least a layer of foamed polymer,
wherein a top-side surface of said foamed polymer is a solidified previously-molten surface of foamed polymer that had been molten and brought into contact with the dark-side surface of said solar cells and that integrally attached to the bottom-side surface of said solar cells;
wherein a bottom-side side surface of said solar cells, and the rollable and flexible floating-capability layer which is formed of foamed polymer, are integrally and mechanically attached to each other via said solidified previously-molten surface of foamed polymer.

7. The device of claim 2,
wherein the one or more self-buoyant low-density rollable and flexible floating-capability layers comprise at least a layer of foamed polymer that is non-detachably bonded to a bottom-surface of the bottom-side surface of said solar cells.

8. The device of claim 2, further comprising:
a bottom-side tension bearing layer, which is rollable and flexible,
and which is attached to a bottom side of the rollable and flexible floating-capability layer;
wherein the bottom-side tension bearing layer provides mechanical support and tension bearing and mechanical integrity to said device.

9. The device of claim 2, further comprising:
a central, sandwiched, tension bearing layer, which is rollable and flexible,
and which is attached and is sandwiched between (i) a top side of the rollable and flexible floating-capability layer, and (ii) a bottom side of the bottom-side surface of said solar cells;
wherein the central, sandwiched, tension bearing layer provides mechanical support and tension bearing and mechanical integrity to said device.

10. The device of claim 2, further comprising:
(I) a bottom-side tension bearing layer, which is rollable and flexible,
and which is attached to a bottom side of the rollable and flexible floating-capability layer;
wherein the bottom-side tension bearing layer provides mechanical support and tension bearing and mechanical integrity to said device;
and also,
(II) a central, sandwiched, tension bearing layer, which is rollable and flexible,
and which is attached and is sandwiched between (i) a top side of the rollable and flexible floating-capability layer, and (ii) a bottom side of the bottom-side surface of said solar cells;
wherein the central, sandwiched, tension bearing layer provides mechanical support and tension bearing and mechanical integrity to said device.

11. The device of claim 10,
wherein at least one of (i) the bottom-side tension bearing layer, and (ii) the central, sandwiched, tension bearing layer,
is a woven fabric that is formed of one or more materials selected from the group consisting of: polypropylene (PP), thermoplastic polymer(s), polyamide, polyimide, aramid, polyethylene terephthalate (PET), glass.

12. The device of claim 10,
wherein at least one of (i) the bottom-side tension bearing layer, and (ii) the central, sandwiched, tension bearing layer,
is a non-woven fabric that is formed of one or more materials selected from the group consisting of: polypropylene (PP), thermoplastic polymer(s), polyamide, polyimide, aramid, polyethylene terephthalate (PET), glass.

13. The device of claim 2,
wherein at least a portion of a top surface of the device is coated with a bird repellant or an animal repellant.

14. The device of claim 2,
wherein at least a portion of a surface of the device is coated with a material that reduces or prevents formation of algae.

15. The device of claim 2,
wherein at least a portion of a bottom surface of the device is coated with a non-stick material that reduces or prevents attachment of objects to a bottom side of the device.

16. The device of claim 2,
wherein at least a portion of a top surface of the device is coated with translucent paint, which provides a camouflage to said device relative to its surrounding, and also enables passage of at least 75% of light through said translucent paint.

17. The device of claim 2,
wherein at least a portion of a top surface of the device is coated with translucent paint or coating or layer, which reduces an Infra-Red (IR) signature of the device.

18. The device of claim 2, further comprising:
a wind-blocking element that surrounds at least a border frame of said device,
and prevents wind from entering into a region of contact between the device and a body of water, and prevents wind from causing said device to fly away or to be dragged away.

19. The device of claim 2,
wherein the device is an autonomously-floating electricity-generating swimming pool cover.

20. The device of claim 2,
wherein each of said solar cells is formed of a single semiconductor wafer having a plurality of non-transcending craters, that penetrate upwardly from the dark-side surface towards the sunny-side surface but do not reach said sunny-side surface;
wherein said non-transcending craters penetrate upwardly into between 80 to 99.9 percent of a height of said semiconductor wafer, and segment said semiconductor wafer into a plurality of miniature sub-regions;
wherein each sub-region has a surface area or a footprint area, measured at the sunny-side surface of the solar cell, in a range of 0.1 to 500 square-millimeters;
wherein said plurality of non-transcending craters and said plurality of miniature sub-regions causes said solar cell to have improved properties of mechanical resilience and mechanical shock absorption and mechanical shock dissipation.

21. The device according to claim 20,
wherein said non-transcending craters do not store and do not include therein any filler material;
wherein said non-transcending craters increase mechanical resilience and mechanical shock absorption and shock dissipation, of each said solar cell, due to existence of a plurality of said non-transcending craters that are arranged in rows and columns and that collectively absorb and dissipate mechanical forces and mechanical shocks.

22. The device according to claim 20,
wherein said non-transcending craters store and include therein a filler material, which provides mechanical resilience and mechanical shock absorption and shock dissipation to each of said solar cells.

23. The device of claim 2,
wherein each of said solar cells is a stand-alone flexible thin-film solar panel.

24. A method of producing the device of claim 2,
the method comprising:
(a) producing the plurality of flexible and rollable and mechanically-resilient solar cells that are inter-connected as said generally planar array;
(b) producing the self-buoyant low-density rollable and flexible floating-capability layer;
(c) integrally attaching and non-removably connecting, via a non-detachable connection mechanism, (i) the plurality of flexible and rollable and mechanically-resilient solar cells, on top of (ii) the self-buoyant low-density rollable and flexible floating-capability layer;
wherein an overall Specific Weight of the entirety of said photovoltaic article is smaller than 1.00.

25. A photovoltaic article, comprising:
(a) a plurality of flexible and rollable and mechanically-resilient solar cells that are inter-connected as a generally planar array that is also flexible and rollable;
(b) a self-buoyant low-density rollable and flexible floating-capability providing layer, which is one of:
(b1) integrally attached and non-removably connected, via a non-detachable connection mechanism, to a bottom side of said generally planar array of flexible and rollable solar cells;
(b2) integrally attached and non-removably connected, as a sandwiched layer within said flexible and rollable solar cells;
(b3) integrally attached and non-removably connected, via a non-detachable connection mechanism, on top of a sunny side of said flexible and rollable solar cells, wherein the self-buoyant low-density rollable and flexible floating-capability providing layer is transparent or translucent to light;
(b4) integrally attached and non-removably connected, via a non-detachable connection mechanism, as an encapsulation structure that encapsulates therein said flexible and rollable solar cells; wherein at least a top-side region of said encapsulation structure is transparent or translucent;
wherein an overall Specific Weight of an entirety of said photovoltaic article is smaller than 1.00.
